(19) United States
(12) Patent Application Publication
(10) Pub. No.: US 2024/0420964 A1
(43) Pub. Date: Dec. 19, 2024

(54) STRIP WITH BEVEL CLEANING

(71) Applicant: Lam Research Corporation, Fremont, CA (US)

(72) Inventors: Leonid BELAU, Pleasanton, CA (US); Eric HUDSON, Berkeley, CA (US)

(21) Appl. No.: 18/701,479

(22) PCT Filed: Oct. 17, 2022
(86) PCT No.: PCT/US2022/046856

§ 371 Date: Apr. 15, 2024

Related U.S. Application Data
(60) Provisional application No. 63/270,764, filed on Oct. 22, 2021.

(51) Int. Cl. H01L 21/311

(52) U.S. Cl. CPC H01L 21/31138

(57) ABSTRACT

A method for stripping a polymer containing sidewall film from etch features and a polymer containing deposition layer from a backside of a bevel of a wafer with a stack with at least one silicon nitride containing layer is provided. A plasma is formed from a stripping gas, the stripping gas comprising a hydrogen (H₂) containing gas and at least one of CO₂, CO, N₂O, NO, or NO₂, wherein the plasma creates radicals from the stripping gas. The wafer is exposed to the radicals, wherein the radicals remove the polymer containing sidewall film and the polymer containing deposition layer.

### CROSS-REFERENCE TO RELATED APPLICATION

This application claims the benefit of priority of U.S. Application No. 63/270,764, filed Oct. 22, 2021, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to a method of forming semiconductor devices on a semiconductor wafer. More specifically, the disclosure relates to etching features in a stack on a wafer where the stack has at least one silicon nitride containing layer. In such processes, a fluoropolymer may be deposited on sidewalls of the etch features. In addition, fluoropolymer may be deposited on the backsides of the bevel of the wafer.

### SUMMARY

To achieve the foregoing and in accordance with the purpose of the present disclosure, a method for stripping a polymer containing sidewall film from etch features and a polymer containing deposition layer from a backside of a bevel of a wafer with a stack with at least one silicon nitride containing layer is provided. A plasma is formed from a stripping gas, the stripping gas comprising a hydrogen (H₂) containing gas and at least one of CO₂, CO, N₂O, NO, or NO₂, wherein the plasma creates radicals from the stripping gas. The wafer is exposed to the radicals, wherein the radicals remove the polymer containing sidewall film and the polymer containing deposition layer.

In another manifestation, a method for processing a stack with at least one silicon nitride containing layer on a wafer with a bevel is provided. At least one feature is etched in the at least one silicon nitride containing layer, wherein the etching the at least one feature forms a polymer containing sidewall film in the at least one feature and a polymer containing deposition layer on a backside of the bevel of the wafer, wherein the etching is provided in a etch chamber with a vacuum. The wafer is moved from the etch chamber to a stripping chamber without breaking the vacuum. The polymer containing sidewall film and the polymer containing deposition layer are stripped, comprising the steps of forming a plasma from a stripping gas, the stripping gas comprising a hydrogen (H₂) containing gas and at least one of CO₂, CO, N₂O, NO, or NO₂, wherein the plasma creates radicals from the stripping gas. The wafer is exposed to the radicals, wherein the radicals remove the polymer containing sidewall film and the polymer containing deposition layer.

In another manifestation, a method for stripping a polymer containing sidewall film from etch features and a polymer containing deposition layer from a backside of a bevel of a wafer with a stack with at least one silicon nitride containing layer is provided. A plasma is formed from a stripping gas, the stripping gas comprising at least one of CO₂, CO, N₂O, NO, or NO₂, wherein the plasma creates radicals from the stripping gas. The wafer is exposed to the radicals, wherein the radicals remove the polymer containing sidewall film and the polymer containing deposition layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2 is a schematic illustration of a platform used in an embodiment.

FIG. 3 is a schematic view of a stripping tool used in an embodiment.

FIG. 4 is an enlarged cross-sectional view of a stack processed in an embodiment.

FIG. 5 is an enlarged cross-sectional view of a bevel of a wafer used in an embodiment.

FIG. 6 is a schematic view of a computer system that may be used in practicing an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry etching of memory holes, using etch technology, is typically associated with deposition of polymer on the wafer surface and backside of the wafer (bevel). Once the wafer is etched it is typically moved from a vacuum environment back into the storage, such as a front opening unified pod (FOUP) in atmosphere, for subsequent treatment. As a result of exposure of reactive species left on the sidewalls of the memory hole structure to atmosphere, there is a high level of sidewall damage resulting in contact profile erosion and defects formation. Such erosion and defect formation are dependent on time and humidity.

Therefore, a post-etch strip of the polymer is a typical procedure used in three dimensional not-and (3D NAND) manufacturing with a silicon nitride (SiN, also known as nitride) layer. A common polymer removal gas is oxygen (O₂) with a forming gas (FG). Forming gas is a diluted hydrogen (H₂) gas. A common forming gas consists of about 4% H₂ and about 96% nitrogen (N₂). Another polymer removal gas is O₂ and N₂ and FG. Such strip chemistries are able to strip polymer from the wafer surface and backside of the wafer. Such strip chemistries damage silicon nitride containing layers in a silicon oxide/silicon nitride/silicon oxide/silicon nitride (ONON) stack resulting in a strong oxidation level and/or erosion of the silicon nitride layers. This results in a significant increase in the contact sidewall roughness and increase contact CD. Limiting O₂ exposure by time or flow is not able to resolve this fundamental limitation. On the other hand, an O₂-free strip is not able to strip polymer from the backside of the wafer. When the polymer is not stripped from the backside of the wafer, particle defects are caused by the polymer peeling and contaminating a chamber, during subsequent processing.

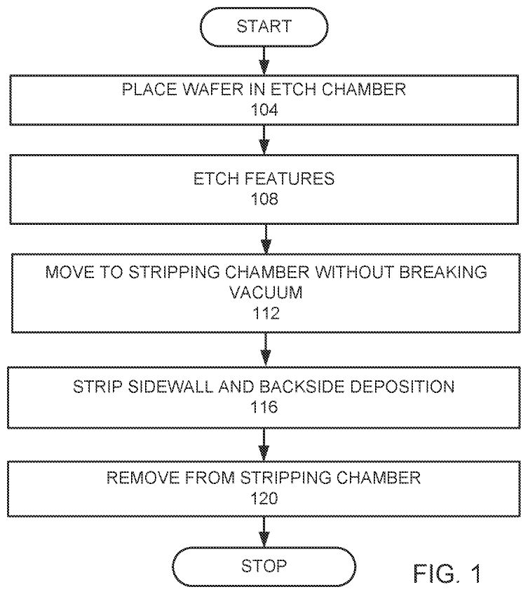

FIG. 1 is a high level flow chart of an embodiment. In this embodiment, a wafer is placed in an etch chamber (step 104). In this embodiment, a stack with a silicon nitride layer is on the wafer. In this embodiment, the stack comprises an ONON stack under a carbon containing mask. A more detailed description of the etch chamber and the related platform used in an embodiment will be described below. Features were etched in a stack on the wafer (step 108). The etching of the features deposits a polymer containing sidewall film on the sidewalls of the etch features and polymer containing deposition layer on the backside bevel of the wafer. In this embodiment, the polymer containing deposition layer and the polymer containing sidewall film are fluoropolymer depositions comprising carbon and fluorine.

The wafer is moved from the etch chamber to a stripping chamber (step 112). In this embodiment, a platform contains both the etch chamber and stripping chamber. The platform is able to move the wafer from the etch chamber to the stripping chamber without breaking vacuum. Maintaining the wafer in a vacuum while being transported from the etch chamber to the stripping chamber prevents the fluoropolymer sidewall films from being exposed to humidity. Humidity may cause the fluoropolymer sidewall films to cause erosion of the stack. By not breaking vacuum while transporting the wafer from the etch chamber to the stripping chamber, the platform reduces damage to the stack.

The polymer containing sidewall film and polymer containing deposition layer are stripped in the stripping chamber (step 116). A plasma is formed from a stripping gas comprising a hydrogen (H₂) containing gas and at least one of carbon dioxide (CO₂), carbon monoxide (CO), nitrous oxide (N₂O), nitric oxide (NO), and nitrogen dioxide (NO₂). In this embodiment, the H₂ containing gas is a forming gas. In this embodiment, the forming gas is H₂ diluted by nitrogen (N₂). In this embodiment, the forming gas has about 4% H₂. In this embodiment, the stripping gas consists essentially of CO₂ and a forming gas of about 4% H₂ and about 96% N₂. Therefore, stripping gas in such embodiments is fluorine and halogen free. In various embodiments, the forming gas may consist essentially of 0.1% to 4% H₂ and 96% to 99.9% N₂ In other embodiments, an inert gas may be added to the stripping gas. Examples of an inert gas may be helium (He), argon (Ar), and Neon (Ne). The plasma creates radicals from the stripping gas. Such radicals may include radicals of H, O, C, NO, and N. The radicals strip the polymer containing sidewall films and polymer containing backside deposition layer with reduced damage or oxidization of the silicon nitride layers. The wafer and stack may be subjected to further processing. The wafer and stack are removed from the platform and exposed to atmosphere.

Using a stripping gas of a forming gas with at least one of CO, CO₂, N₂O, NO, or NO₂ provides a unique capability to strip polymer from the wafer surface, pattern structure sidewalls, and backside of the wafer (bevel). This combination enables a high polymer strip rate while also providing significantly lower surface oxidation in comparison to stripping gases of O₂ and the forming gas. Oxidation and/or erosion of the SiN layer using a stripping gas with O₂ is unacceptable for some applications. If the stripping gas is the forming gas alone, the fluorocarbon deposition layer on the backside of the wafer is not sufficiently removed. As a result, the remaining fluorocarbon deposition layer will become a contaminant in subsequent processing, increasing the number of device defects.

In some embodiments, the stripping gas provides a flow of CO₂ in the range from 30 sccm to 3 liters per minute. In other embodiments, the stripping provides CO₂ with a flow rate in the range of 150-1000 sccm. In some embodiments, the ratio of the flow rate of CO₂ to the flow rate of the forming gas is in the range of 1:100 to 5:1.

In embodiments that etch SiN containing layers at wafer-support cryogenic temperatures of less than −10° C., ammonium salts (NH₄X) may deposit with the polymer containing deposition on the backside of the wafer bevel. The use of the stripping gas with CO₂ and a forming gas has been found to increase the removal rate of ammonia salts along with polymer containing deposition. The removal of ammonia salts reduces contaminants in later processes. As a result, the stripping gas provides improved stripping after a cryogenic etch process. In other embodiment, a cryogenic etch process is performed at a temperature of less than −10° C.

Other embodiments may use a stripping gas consisting essentially of CO₂ and H₂. For example, the stripping gas may be 90% to 99.9% CO₂ and 0.1% to 10% H₂. Therefore, the stripping gas may consist essentially of an H₂ containing gas and least one of CO₂ or CO N₂O, NO, or NO₂. The H₂ containing gas may consist essentially of a forming gas of N₂ and H₂ or only H₂. During the stripping, the wafer temperature is maintained at a temperature in the range from 20° C. to 500° C. A pressure of about 750 mT (millitorr) is provided. Generally, the pressure is in the range of 100-2000 mT.

In other embodiments, the stripping gas is H₂ free or has less than 0.1% H₂. In such an embodiment, the stripping gas consists essentially of at least one of CO₂, CO, N₂O, NO, or NO₂. In other such embodiments, the stripping gas consists essentially of an inert gas and at least one of CO₂, CO, N₂O, NO, or NO₂, wherein the inert gas is at least one of He, Ne, Ar, or N₂.

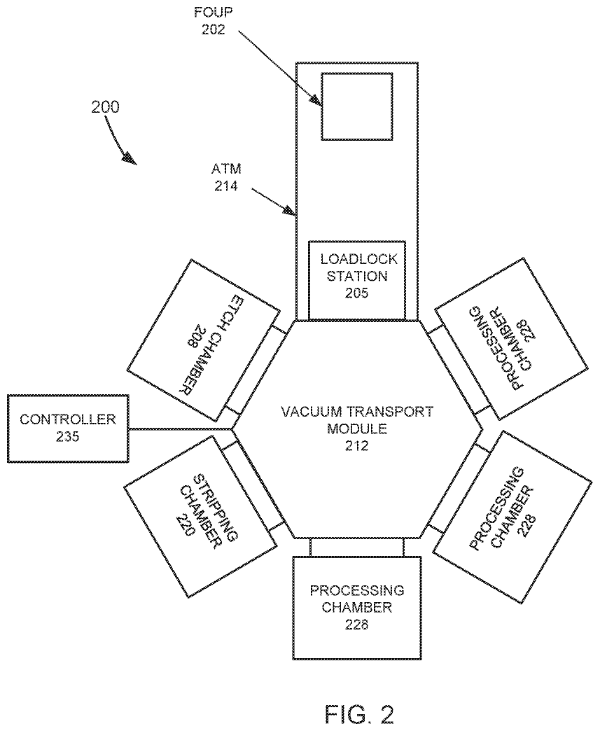

FIG. 2 is a top schematic view of a platform 200, which uses an embodiment. A FOUP 202 houses the unprocessed wafers before they are processed and then holds the treated wafers once all processing is complete in the platform 200. The FOUP 202 can hold many wafers, often as many as 25. An atmosphere transport module (ATM) 214 is used to transport wafers to and from the FOUP 202. A load lock station 205 represents at least one device that operates to transfer the wafer back and forth between the atmosphere of the ATM 214 and the vacuum of a vacuum transport module (VTM) 212. The VTM 212 is part of the platform 200 that connects a plurality of processing chambers. There may be different types of processing chambers. In this embodiment, the plurality of processing chambers comprises an etch chamber 208, a stripping chamber 220, and additional processing chambers 228. In this embodiment, the etch chamber 208 is a dielectric etch chamber that is capacitively coupled. In other embodiments, the etch chamber 208 may be inductively coupled. A robotic system within the vacuum transport module 212 uses an end effector to move a wafer between the load lock station 205 and the processing chambers. The ATM 214 uses a robotic system to transfer wafers between the FOUP 202 and the load lock station 205. A controller 235 may be used to control the entire platform 200 or a plurality of controllers 235 may be used to control different parts of the platform 200 and different processing chambers.

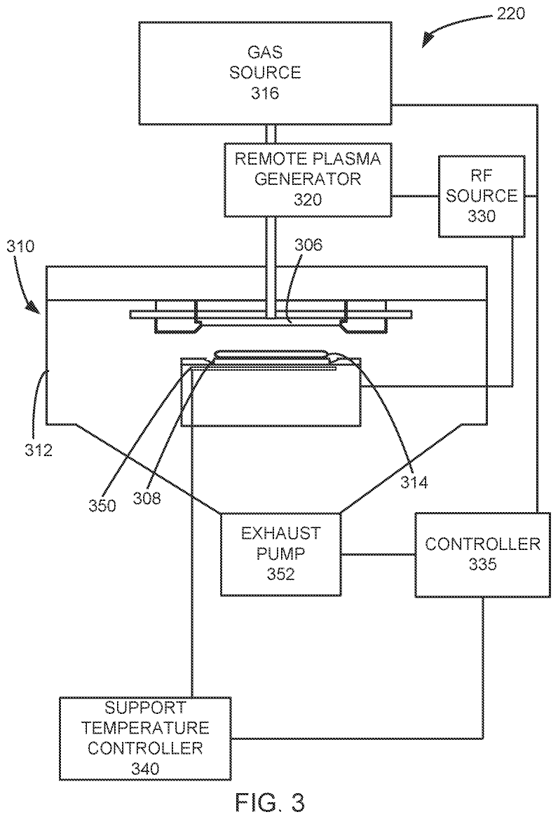

FIG. 3 is a schematic view of a stripping chamber 220 which may be used in an embodiment. In one or more embodiments, the stripping chamber 220 comprises a showerhead 306 providing a gas inlet and wafer support 308, within a reactor chamber 310, enclosed by a chamber wall 312. Within the reactor chamber 310, a wafer 314 is positioned over the wafer support 308. A gas source 316 is connected to a remote plasma generator 320. The remote plasma generator 320 is connected to the reactor chamber 310 through the showerhead 306. A radio frequency (RF) source 330 provides RF power at one or more frequencies of 27 megahertz (MHz), 13.56 MHz, 60 MHz, 2 MHz, or 400 kHz to the remote plasma generator 320. A support temperature controller 340 is used to control the temperature of the wafer support 308. A controller 335 is controllably connected to an exhaust pump 352, the support temperature controller 340, and the gas source 316. In some embodiments, capacitively coupled or inductively coupled energy may be provided to the stripping chamber 220 using an electrode or helical coil. In an embodiment, 200 W to 5000 W of RF energy is provided to the stripping chamber 220, using inductively coupled RF power to produce radicals in the stripping chamber 220. In other embodiments, the stripping chamber 220 does not use a remote plasma but instead generates a plasma in the stripping chamber.

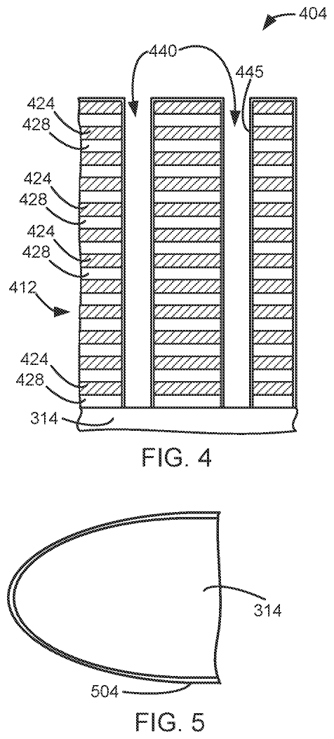

FIG. 4 is an enlarged schematic cross-sectional view of part of a stack 404 over part of the wafer 314, after etching of etch features 440 in the stack. In this embodiment, the stack 404 comprises a plurality of bilayers 412. In this example, one or more layers may be disposed between the wafer 408 and the plurality of bilayers. In this embodiment, each bilayer 412 includes a layer of silicon oxide 424 and a layer of silicon nitride 428. A fluoropolymer sidewall film 445 has been deposited on the sidewalls of the etch features 440. FIG. 5 is an enlarged cross-sectional view of the bevel of the wafer 314 with fluoropolymer deposition layer 504. Various embodiments are able to strip the fluoropolymer sidewall 445 and the fluoropolymer deposition layer 504 while minimizing erosion and oxidation of the layers of silicon nitride 428.

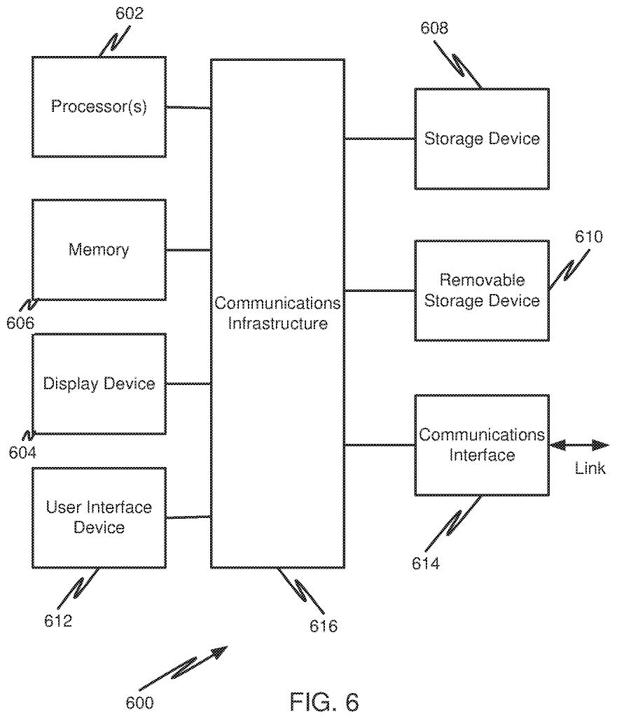

FIG. 6 is a high level block diagram showing a computer system 600, which is suitable for implementing the controllers 235 and 535 used in embodiments. The computer system 600 may be one or more computer systems for implementing the controllers 235 and 535. The computer system may have many physical forms ranging from an integrated circuit, a printed circuit board, and a small handheld device, up to a huge supercomputer. The computer system 600 includes one or more processors 602, and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communication interface 614 (e.g., wireless network interface). The communication interface 614 allows software and data to be transferred between the computer system 600 and external devices via a link. The system may also include a communications infrastructure 616 (e.g., a communications bus, cross-over bar, or network) to which the aforementioned devices/modules are connected.

The information transferred via communications interface 614 may be in the form of signals such as electronic, electromagnetic, optical, or other signals capable of being received by communications interface 614, via a communication link that carries signals and may be implemented using wire or cable, fiber optics, a phone line, a cellular phone link, a radio frequency link, and/or other communication channels. With such a communications interface, it is contemplated that the one or more processors 602 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as one produced by a compiler, and files containing higher level code that are executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for stripping a polymer containing sidewall film from etch features and a polymer containing deposition layer from a backside of a bevel of a wafer with a stack with at least one silicon nitride containing layer, comprising:
forming a plasma from a stripping gas, the stripping gas comprising:
a hydrogen (H₂) containing gas; and
at least one of CO₂, CO, N₂O, NO, or NO₂, wherein the plasma creates radicals from the stripping gas; and
exposing the wafer to the radicals, wherein the radicals remove the polymer containing sidewall film and the polymer containing deposition layer.

2. The method, as recited in claim 1, wherein the H₂ containing gas is a forming gas comprising:
H₂; and
N₂, wherein the forming gas is 0.1% to 4% H₂.

3. The method, as recited in claim 2, wherein the stripping gas consists essentially of the forming gas and at least one of CO₂, CO, N₂O, NO, or NO₂.

4. The method, as recited in claim 2, wherein the stripping gas consists essentially of the forming gas, at least one inert gas, and at least one of CO₂, CO, N₂O, NO, or NO₂.

5. The method, as recited in claim 1, wherein the stripping gas is halogen free.

6. A method for processing a stack with at least one silicon nitride containing layer on a wafer with a bevel, comprising:
etching at least one feature in the at least one silicon nitride containing layer, wherein the etching the at least one feature forms a polymer containing sidewall film in the at least one feature and a polymer containing deposition layer on a backside of the bevel of the wafer, wherein the etching is provided in a etch chamber with a vacuum;
moving the wafer from the etch chamber to a stripping chamber without breaking the vacuum;
stripping the polymer containing sidewall film and the polymer containing deposition layer, comprising the steps of:
forming a plasma from a stripping gas, the stripping gas comprising:
a hydrogen (H₂) containing gas; and
at least one of CO₂, CO, N₂O, NO, or NO₂, wherein the plasma creates radicals from the stripping gas; and
exposing the wafer to the radicals, wherein the radicals remove the polymer containing sidewall film and the polymer containing deposition layer.

7. The method, as recited in claim 6, wherein the H₂ containing gas is a forming gas comprising:
H₂; and
N₂, wherein the forming gas is 0.1% to 4% H₂.

8. The method, as recited in claim 7, wherein the stripping gas consists essentially of the forming gas and at least one of CO₂, CO, N₂O, NO, or NO₂.

9. The method, as recited in claim 7, wherein the stripping gas consists essentially of the forming gas, at least one inert gas, and at least one of CO₂, CO, N₂O, NO, or NO₂.

10. The method, as recited in claim 6, wherein the stripping gas is halogen free.

11. The method, as recited in claim 6, wherein the stripping the polymer is performed at a temperature in a range of 20° C. to 500° C.

12. The method, as recited in claim 6, wherein the polymer containing deposition layer and the polymer containing sidewall comprises a fluoropolymer.

13. The method, as recited in claim 12, wherein the polymer containing deposition layer further comprises an ammonia salt.

14. A method for stripping a polymer containing sidewall film from etch features and a polymer containing deposition layer from a backside of a bevel of a wafer with a stack with at least one silicon nitride containing layer, comprising:
forming a plasma from a stripping gas, the stripping gas comprising:
at least one of CO₂, CO, N₂O, NO, or NO₂, wherein the plasma creates radicals from the stripping gas; and
exposing the wafer to the radicals, wherein the radicals remove the polymer containing sidewall film and the polymer containing deposition layer.

15. The method, as recited in claim 14, wherein the stripping gas consists essentially of at least one of CO₂, CO, N₂O, NO, or NO₂.

16. The method, as recited in claim 14, wherein the stripping gas consists essentially of at least one inert gas, and at least one of CO₂, CO, N₂O, NO, or NO₂.
